(19) United States
(12) Patent Application Publication
(10) Pub. No.: US 2025/0098342 A1
(43) Pub. Date: Mar. 20, 2025

(54) CONVEX PHOTODIODE IMAGING ARRAY

(71) Applicant: COMMISSARIAT A L'ENERGIE ATOMIQUE ET AUX ENERGIES ALTERNATIVES, Paris (FR)

(72) Inventor: Johan ROTHMAN, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/830,671

(22) Filed: Sep. 11, 2024

(30) Foreign Application Priority Data
Sep. 14, 2023 (FR) 2309705

(51) Int. Cl. H01L 27/146

(52) U.S. Cl. CPC H10F 39/18; H10F 39/026; H10F 39/8033

(57) ABSTRACT

An array of at least two photodiodes, wherein each photodiode includes an absorption region and a capture region, the capture region including an electrically conductive pad, the absorption region being in contact with the capture region, the absorption region being configured to absorb an incident radiation on the photodiode and to enable a diffusion of charge carriers, in which each absorption region is separated from the other absorption regions, and wherein the absorption region of each photodiode has a convex shape towards the incident radiation.

### TECHNICAL FIELD

The present invention relates to the production of an array of photodiodes arranged on a semiconductive substrate. It has, for example, a particularly advantageous application in the field of imaging, in particular, low pixel pitch and high operating temperature infrared imaging.

### PRIOR ART

Conventional photodiode arrays have a so-called planar architecture, in which the photodiodes of the array are arranged periodically over a flat surface. This planar architecture has the advantage of a relatively simple manufacture. In return, it has limitations in terms of performance, due to the diffusion of the charge carriers photogenerated in the absorption region of the radiation within each photodiode to the neighbouring photodiodes. This contamination of charge carriers known under the term “crosstalk”, causes the deterioration of performance of a high-density photodiode array, by reducing the modulation transfer function (MTF).

In order to reduce the crosstalk, it is possible to reduce the thickness of the absorption layer. However, this solution tends to reduce the quantum yield of the array.

Another solution consists of manufacturing a p-n junction photodiode array which is vertical with respect to the substrate. The contact between the photodiodes and a readout integrated circuit (ROIC) is established by etching an opening between the photodiodes through the multilayers arriving up to the electric pads. Producing such a high photodiode density array on thick multilayers appears difficult and able to cause a loss of quantum yield of the array, due to the large volume occupied by the openings etched between the photodiodes.

Another preexisting solution is to manufacture mesa-shaped photodiodes, by etching sufficiently deep trenches between the photodiodes, in order to physically separate them. This solution makes it possible to confine the charge carriers in each pixel, and to overcome the crosstalk problem. However, the presence of the trenches can highly reduce the quantum yield and increase the leakage currents. In addition, the MTF can also be reduced by the diffusion of the incident radiation on the flanks of the trenches to the neighbouring photodiodes.

With the aim of concentrating the incident radiation at the centre of each pixel of the array, a strategy effectively used consists of depositing a microlens array on the photodiode array. Each microlens enables the concentration of the incident radiation at the centre of each pixel in a focal point coinciding with a region of multiple photodetectors. This solution is difficult to implement, as it requires manufacturing steps on the rear face of the array to form 3D microstructures. In addition, the MTF can be limited by the diffraction of the incident radiation at the interface between two microlenses, as well as by the lateral diffusion of the charge carriers in the case of a planar photodiode array.

The present invention aims to resolve at least partially the problems mentioned above by proposing an array architecture, in which the photodiodes are spaced apart from one another, and in which the geometric shape of the active region of each photodiode enables a better concentration of the radiation at the centre of the pixel.

### SUMMARY

To achieve the aim mentioned above, according to an embodiment, an array of at least two photodiodes is provided, in which each photodiode comprises an absorption region and a capture region, the capture region comprising an electrically conductive pad, the absorption region being in contact with the capture region, the absorption region being configured to absorb an incident radiation on the photodiode and to enable a diffusion of charge carriers, and in which each absorption region is separated from the other absorption regions, characterised in that the absorption region of each photodiode has a convex shape towards the incident radiation.

Each photodiode of the array further comprises, according to a non-limiting aspect, a coverage region based on a first semiconductor, the coverage region covering an upper face of the absorption region facing the incident radiation.

One of the advantages of this architecture is the physical separation of the absorption regions. This has the effect of electrically isolating the photodiode and of reducing the crosstalk in the array.

A second advantage is the convex shape of the absorption region, which makes it possible to optimise the concentration of the radiation at the centre of each photodiode, which improves the quantum yield, reduces the volume of the dark current, increases the operating temperature, as well as the MTF of the array.

### BRIEF DESCRIPTION OF THE FIGURES

The aims, objectives, as well as the features and advantages will best emerge from the detailed description of an embodiment of the latter, which is illustrated by the following accompanying drawings, in which:

FIG. 1 represents a top view of an imaging array comprising several photodiodes.

FIG. 2 represents a cross-sectional view of an array comprising a least two photodiodes.

FIGS. 3A and 3B represent two embodiments of the photodiode array according to the invention. FIG. 3A represents a first embodiment, in which the absorption region and the coverage region, on the one hand, and the collection region, on the other hand, have distinct doping types.

FIG. 3B represents a second embodiment of the array according to the invention, in which the absorption region and the collection region, on the one hand, and the coverage region, on the other hand, have distinct doping types.

The drawings are given as examples and are not limiting of the invention. They constitute principle schematic representations, intended to facilitate the understanding of the invention, and are not necessarily to the scale of practical applications. In particular, the dimensions are not representative of reality.

### DETAILED DESCRIPTION

Before starting a detailed review of embodiments of the invention, below, optional features are stated, which can optionally be used in association or alternatively:

According to an advantageous embodiment, each photodiode 100a, 100b of the array 1 comprises an absorption region 20 and a capture region 70. The capture region 70 comprises an electrically conductive pad 50, and the absorption region 20 is in contact with the capture region 70. The absorption region 20 is configured to absorb an incident radiation on the photodiode and to enable a diffusion of charge carriers. Each absorption region 20 is separated from the other absorption regions 20. The absorption region 20 of each photodiode 100a, 100b has a convex shape towards the incident radiation. This makes it possible to increase the distance travelled by the radiation inside the absorption region 20, and consequently, to improve the absorption of the radiation and the quantum yield of the array.

According to an advantageous embodiment, each photodiode 100a, 100b further comprises a coverage region 10 based on a first semiconductor. The coverage region 10 covers an upper face 20a of the absorption region 20 facing the incident radiation.

Advantageously, the coverage region 10 has a first bandgap energy E₁₀ greater than 0.41 eV. This favours the transparency of the coverage layer 10 at wavelengths greater than 3 μm.

According to a preferable example, the upper face 10a of the coverage region 10 facing the incident radiation, has a convex surface to the incident radiation.

Preferably, the absorption region 20 of each photodiode 100a, 100b has a curvilinear convex shape, preferably a circular arc shape, preferably a semi-sphere. According to another example, the absorption region 20 of each photodiode 100a, 100b has a conic or truncated shape. According to another example, the absorption region 20 of each photodiode 100a, 100b has a truncated pyramid shape.

Advantageously, the absorption region 20 has a second bandgap energy E₂₀, with E₁₀>E₂₀. The high value of the bandgap energy E₁₀ enables the reduction of the impact of defects present on the upper face 20a of the photodiode.

Preferably, the capture region 70 further comprises a collection region 30 located between the absorption region 20 and the electrically conductive pad 50. The collection region 30 is based on a third semiconductor. The collection region 30 is in contact with the absorption region 20 and with the electrically conductive pad 50.

Preferably, each photodiode 100a, 100b comprises a passivation layer 40 in contact with a lower face 20b of the absorption region 20 opposite an upper face 20a of the absorption region 20 facing the incident radiation. The passivation layer 40 has openings 45a, 45b, each opening 45a, 45b, facing the absorption region 20 of a distinct photodiode 100a, 100b. The capture region 70 of said photodiode 100a, 100b extends into said opening 45a, 45b.

According to an example, the absorption region 20 contains a gap opening zone 60 extending from a lower face 20b of the absorption region 20 opposite an upper face 20a of the absorption region 20 facing the incident radiation. The gap opening zone 60 has a variation of its bandgap energy along a direction, called normal direction, substantially perpendicular to the lower face 20b of the absorption region 20.

According to an example, the absorption region 20 has a maximum height h₂₀ along the normal direction and the gap opening zone 60 has a maximum height h₆₀ along the normal direction, with h₆₀≤0.5*h₂₀, preferably h₆₀≤0.3*h₂₀, preferably h₆₀≤0.1*h₂₀.

According to an example, the gap opening zone 60 has a minimum height h₆₀ along the normal direction, with preferably h₆₀≥100 nm.

According to an embodiment, the coverage region 10 and the absorption region 20 are doped, the coverage region 10 has the same doping type as that of the absorption region 20, and further, the collection region 30 has a doping type opposite that of the absorption region 20.

According to an embodiment, the coverage region 10 and the absorption region 20 are doped, the coverage region 10 has a doping type opposite that of the absorption region 20, and further, the collection region 30 and the absorption region 20 have the same doping type.

According to an example, the coverage regions 10 of at least two of the photodiodes 100a, 100b form a continuous layer.

According to a preferred example, the absorption region 20 has a doping level less than 10¹⁶ cm⁻³, preferably less than 2*10¹⁵ cm⁻³, preferably less than 2*10¹⁴ cm⁻³. This enables the operation of the photodiode as an operating high-temperature depleted PIN photodiode.

According to another preferred example, the coverage region 10 has a doping level greater than 10¹⁶ cm⁻³, preferably greater than 10¹⁷ cm⁻³. This leads to an effective gap opening by Moss-Burstein effect for an N-type doping in the coverage region 10.

Preferably, the collection region 30 has a doping level greater than 10¹⁶ cm⁻³.

According to a preferred example, the absorption region 20 has a second bandgap energy E₂₀ of between 0.23 and 0.3 eV.

According to an example, the absorption region 20 is based on a second semiconductor, the first semiconductor, the second semiconductor and the third semiconductor are the same, and are, for example, CdHgTe-based. The bandgap energy is thus controlled, by varying the percentage of cadmium (Cd) in the CdHgTe composition.

According to a preferred example, the absorption region 20 has an N-type doping.

According to an example, the absorption region 20 is CdHgTe-based. According to an example, the coverage region 10 is CdHgTe-based. According to an example, the collection region 30 is CdHgTe-based. The absorption region 20, the coverage region 10 and the collection region 30 can all be material-based, without this material being presented in the same composition in the three regions. The percentages of each of the elements constituting the material can vary from one region to another. For example, when the absorption region 20, the coverage region 10 and the collection region 30 are all CdHgTe-based, the proportion of cadmium can vary from one region to another.

It is specified that, in the scope of the present invention, the terms “on”, “surmounts”, “covers”, “underlying”, “opposite” and their equivalents do not necessarily mean “in contact with”. Thus, for example, the deposition, the transfer, the bonding, the assembly or the application of a first layer on a second layer, does not compulsorily mean that the two layers are directly in contact with one another, but means that the first layer covers at least partially the second layer by being, either directly in contact with it, or by being separated from it by at least one other layer or at least one other element.

A layer can moreover be composed of several sublayers of one same material or of different materials.

By a substrate, a layer, a device “based on” a material M, this means a substrate, a layer, a device comprising this material M only or this material M and optionally other materials, for example, alloy elements, impurities or doping elements. Thus, a material based on a III-V material can comprise a III-V material added with dopants.

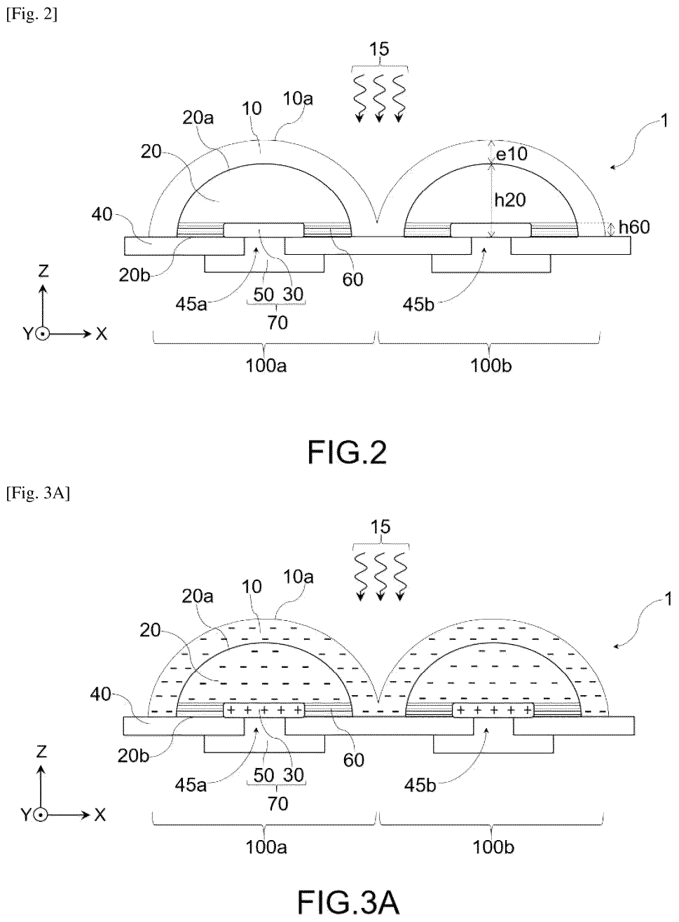

A preferably orthonormal system, comprising the axes X, Y, Z is represented in FIG. 2. This system is applicable by extension to the other figures.

In the present patent application, thickness will preferably be referred to for a layer, and height for a structure or a device. The height is taken perpendicularly to the horizontal plane XY. The thickness is taken along a direction normal to the main extension plane of the layer. Thus, a layer typically has a thickness along Z, when it extends mainly along the horizontal plane XY, and a projecting element, for example, an isolation trench, has a height along Z. The relative terms “on”, “under”, “underlying” refer preferably to positions taken along the direction Z.

The terms “substantially”, “about”, “around” mean “plus or minus 10%, preferably plus or minus 5%”.

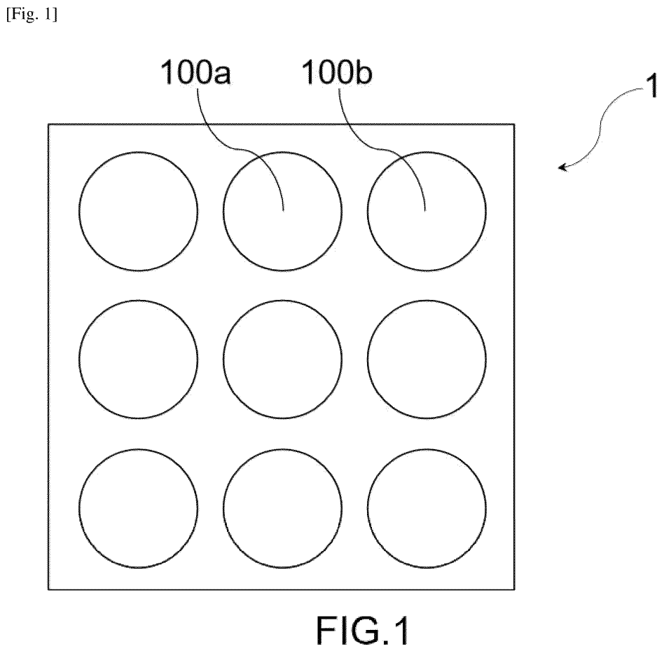

The invention relates to an array 1 of photodiodes 100a, 100b being, for example, disposed on a semiconductive substrate, such as illustrated as a top view in FIG. 1. The array 1 comprises at least two photodiodes 100a and 100b. The array 1 can also be described as a pixel array. Each of the photodiodes 100a, 100b advantageously forms part of a pixel. A pixel can comprise one single photodiode 100a, 100b or a plurality of photodiodes 100a, 100b.

During the use of the array 1, the latter is exposed to an incident radiation 15. This incident radiation preferably has a non-zero component along the direction Z.

According to an embodiment, each photodiode 100a, 100b comprises the elements illustrated in FIG. 2, which will be detailed below.

Each photodiode 100a, 100b comprises an absorption region 20 based on a semiconductive material. This absorption region 20 enables the absorption of the incident radiation 15 to the photodiode 100a, 100b and the generation of electron-hole pairs. The charge carriers are then diffused through the absorption region 20 to a capture zone 70.

The absorption regions 20 of distinct photodiodes 100a, 100b are separated or spaced apart physically from one another. In other words, there is no contact between the absorption regions 20 of the array 1. This makes it possible to guarantee a confinement of the charge carriers photogenerated in each of the absorption regions 20, and, consequently, to guarantee a good MTF level.

With the aim of improving the sensitivity of the photodiode 100a, 100b to the incident radiation, the geometric shape of the absorption region 20 is optimised in order to concentrate the incident radiation at the centre of the photodiode 100a, 100b.

According to the invention, the absorption region 20 of each photodiode 100a, 100b has a convex shape towards the incident radiation 15. The convex geometric shape of the absorption region 20 can adopt one of the following configurations: a shape, the upper face of which facing the incident radiation 15 is curvilinear convex, preferably circular arc-shaped, preferably a semi-sphere, a truncated cone, a truncated pyramid, or any three-dimensional geometric shape E, such as any segment having its ends in E is fully included in E, and the upper face of which facing the incident radiation enables the concentration of the radiation at the centre of the lower face of E, opposite the upper face of E. The convex shape is advantageously configured to deviate the propagation direction of the radiation propagating in the photodiode of the direction of the incident radiation. The convexity of the absorption region 20 is given by the shape of its upper face 20a. The absorption region 20 also has a lower face 20b facing the upper face 20a.

The convex shape of the region 20 enables the refraction of the incident radiation to the centre of the photodiode 100a, 100b which makes it possible to increase the distance travelled by the radiation inside the absorption region 20, and consequently, to improve the absorption of the yield and the quantum yield of the array 1. It is important to note that the refraction of the radiation is greater when the radiation is incident on the flanks of the upper face 20a of the absorption region 20, occupying a main part of the surface of the photodiode.

The absorption region 20 is manufactured on the basis of a semiconductive material, preferably one from among the following materials: a II-VI semiconductor, such as CdHgTe (or HgCdTe), a III-V semiconductor, for example a solid material like InAsSb, or also an effective energy band structure material, being able, for example, to be obtained in the case of II-type super arrays.

The absorption region 20 is advantageously doped, preferably with an N-type doping. It has, moreover, a bandgap energy E₂₀. Said energy is adapted, in order to favour the detection of the radiation in a given spectral band, preferably in the mid-infrared. The value of E₂₀ is preferably between 0.23 eV and 0.3 eV at a given operating temperature.

The doping level of the absorption region 20 is advantageously less than 10¹⁶ cm⁻³, preferably less than 2*10¹⁵ cm⁻³, preferably less than 2*10¹⁴ cm⁻³. The low doping of the absorption region 20 enables the operation of the photodiode as a high operating temperature depleted PIN photodiode. The reduction, even the removal of free carriers within the absorption region 20 makes it possible to reduce, even remove the Auger generation of the dark current and obtain a very high operating temperature. In this case, the electric separation of the absorption regions 20 of the different photodiodes removes the modulation of the field according to the current detected when the photodiodes are hybridised with a CMOS circuit operating in direct injection. Thus, the operation of a photodiode array 1, the absorption regions 20 of which are depleted according to this embodiment is stabler than that expected for a matrix produced according to the prior art.

In order to extract the charge carriers to a silicon multiplexing circuit often produced in CMOS (complementary metal oxide semiconductor) technology, each photodiode 100a, 100b further comprises a capture region 70 in contact with the absorption region 20, as illustrated in FIG. 2. The capture region 70 comprises an electrically conductive pad 50 typically connected to an input node of the CMOS circuit.

The capture region 70 can further comprise a collection region 30 located between the absorption region 20 and the electrically conductive pad 50. The collection region 30 is based on a semiconductive material, preferably the same material as that constituting the absorption region 20, like CdHgTe, for example. In the case where the collection region 30 and the absorption region 20 are based on the same semiconductive material, it is possible that the composition of this semiconductive material is distinct from one region 30 to another 20. For example, the cadmium present in the CdHgTe constituting the collection region 30 can be found in a different percentage than in the absorption region 20. The collection region 30 is in contact with the absorption region 20 and with the electrically conductive pad 50, and preferably ensures the transfer of the charge carriers from the absorption region 20 to the pad 50.

The collection region 30 advantageously has a doping level greater than 10¹⁶ cm⁻³. This makes it possible to obtain a good ohmic contact with the pad 50 and to limit the extension of the space charge zone in the region 30. The collection region 30 can have a doping type opposite that of the absorption region 20, according to a first embodiment, or the same doping type as that of the absorption region 20, according to a second embodiment. These two particular embodiments will be described in detail below.

Each photodiode 100a, 100b preferably comprises a passivation layer 40 which ensures its electrical, mechanical and chemical protection. The passivation layer 40 is preferably based on a material of same group of semiconductors as the materials forming the coverage region 10, the absorption region 20 and the collection region 30. When the coverage region 10, the absorption region 20 and the collection region 30 are based on a II-VI material, for example CdHgTe, the passivation layer 40 is made based on another II-VI semiconductive material such as ZnS. The passivation layer 40 is in contact with a part of the lower face 20b of each photodiode 100a, 100b. It has openings 45a, 45b, each opening 45a, 45b facing the absorption region 20 of a distinct photodiode 100a, 100b. The capture region 70 extends into the openings 45a, 45b of the passivation layer 40 to ensure an electric contact with the absorption region 20.

Each photodiode 100a, 100b further preferably comprises a coverage region 10 based on a semiconductive material, preferably the same material as that constituting the absorption region 20 like CdHgTe, for example. In the case where the coverage region 10 and the absorption region 20 are based on the same semiconductive material, it is possible that the composition of this semiconductive material is distinct from one region 10 to another 20. For example, the cadmium present in the CdHgTe constituting the coverage region 10 can be found in a different percentage than in the absorption region 20. The coverage region 10 covers the upper face 20a of the absorption region 20 facing the incident radiation, preferably in its entirety. The coverage region 10 can cover the entire surface of the array 1 continuously, such that it is contiguous between the photodiodes 100a and 100b, or it can cover each distinct photodiode 100a, 100b in a non-contiguous manner. The coverage region 10 has a preferably constant or conform thickness. This thickness is typically between 0.1*h₂₀ and 0.25*h₂₀. Advantageously, the coverage region 10 separates the photodiodes 100a, 100b from one another in the plane XY. Thus, the coverage region 10 makes it possible to prevent the diffusion between the photodiodes 100a and 100b of the array 1, minor carriers generated in the absorption region 20. This favours an increase of the MTF of each photodiode 100a, 100b.

The upper face 10a of the coverage region 10 facing the incident radiation 15 preferably has a convex shape towards the incident radiation. Said upper face 10a of the coverage region 10 can adopt a curvilinear convex shape, preferably circular arc-shaped, preferably a semi-sphere surface shape, a truncated cone surface shape, or also a surface shape of a truncated pyramid. Whatever the geometric shape of the upper face 10a of the coverage region 10, it can cover the photodiodes 100a, 100b of the array 1, either continuously contiguously between the photodiodes 100a and 100b, or non-contiguously between the different photodiodes. Moreover, it is advantageously provided that the upper face 10a of the coverage region 10 and the upper face 20a of the absorption region 20 have geometries of the same type. For example, according to an advantageous embodiment, the upper face 10a of the coverage region 10 and the upper face 20a of the absorption region 20 both have a circular arc shape, preferably concentric.

The coverage region 10 has a bandgap energy E₁₀ with E₁₀>E₂₀. Preferably, said bandgap energy E₁₀ of the coverage layer 10 is greater than 0.41 eV. This favour the transparency of the coverage layer 10 at wavelengths greater than 3 μm. The high value of the bandgap energy E₁₀ further enables the reduction of the impact of the defects present on the upper face 10a of the photodiode which can induce an excess dark and noise current. It also makes it possible to reduce the absorption of the incident radiation 15 in the coverage region 10.

The coverage region 10 can have the same doping type as that of the absorption region 20, according to a first embodiment, or a doping type opposite that of the absorption region 20 according to a second embodiment. Preferably, the coverage region 10 has a doping level greater than 10¹⁶ cm⁻³, preferably greater than 10¹⁷ cm⁻³.

The high doping level of the coverage region 10 leads to an effective gap opening by Moss-Burstein effect in the case where the coverage region 10 and the absorption region 20 have an N-type doping. This gap opening induces a curvature of the valence band in the coverage region 10. This has the effect of limiting the interaction between the minor charge carriers and the defects present on the upper face 10a of the photodiode, in favour of a reduction of dark current and an increase of the quantum yield of each photodiode.

Within a photodiode 100a, 100b, the coverage region 10 and the collection region 30 preferably allow both to have a rotation symmetry about one same axis (parallel to the axis Z in the figures). Associated with the reduction of the number of free carriers within the absorption region 20, the symmetrical configuration of the coverage region 10 around the collection region 30 enables a very high, even complete depletion of the absorption region 20, with very little, even without non-depleted pocket. This makes it possible to limit the dark current.

According to a variant of an embodiment of the invention, the absorption region 20 contains a gap opening zone 60 which extends from the lower face 20b of the absorption region 20, as illustrated in FIG. 2. The gap opening zone 60 has a variation of its bandgap energy along a direction, called normal direction, substantially perpendicular to the lower face 20b of the absorption region 20. The normal direction corresponds to the direction Z in the figures. The gap opening zone 60 preferably extends all around the collection region 30 projecting into the plane XY.

The absorption region 20 has a maximum height h₂₀ typically measured along the normal direction. In the case where the absorption region 20 has the shape of a spherical cap, the maximum height h₂₀ typically corresponds to the height of the spherical cap. In the case where the absorption region 20 has a truncated or pyramidal shape, the maximum height h₂₀ typically corresponds to the height measured between its small base and its large base. The gap opening zone 60 has a maximum height h₆₀ along the normal direction. Advantageously, h₆₀≤0.5*h₂₀, preferably h₆₀≤0.3*h₂₀, preferably h₆₀≤0.1*h₂₀. The height h₆₀ of the gap opening zone 60 is preferably greater than or equal to 100 nm.

According to a variant of an embodiment of the invention, the upper face 10a of the coverage region 10 is covered with a transparent layer to the incident radiation at the photodiodes 100a, 100b of the array 1. This layer aims to improve the transmission of the incident radiation to the absorption region 20, thanks to its refraction index chosen carefully according to the application.

According to a variant of the embodiment of the invention, an electrically conductive region disposed outside of the photodiode array 1, makes it possible to establish an ohmic contact with the coverage region 10.

By varying the doping type of the absorption 20, coverage 10 and collection regions 30, two main embodiments of the invention can optionally be considered.

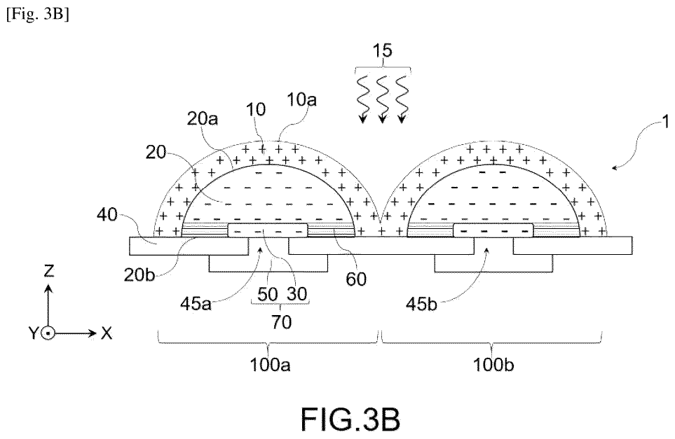

According to the first of these two embodiments, as illustrated in FIG. 3A, the coverage region 10 has the same doping type as that of the absorption region 20, preferably N-type. Furthermore, the collection region 30 has a doping type opposite that of the absorption region 20, preferably P-type, thus forming a p-n junction with the absorption region 20 in each photodiode 100a, 100b of the array 1. The p-n junction thus formed induces the separation of the charges photogenerated in the absorption region 20 and their extraction to the pad 50. In the case of an N-type doping in the coverage region 10 and the absorption region 20, an effective gap opening is possible. This effective gap opening and the separation of the absorption regions of each photodiode 100a, 100b, imply that the charge carriers separated by each p-n junction of an individual photodiode are therefore those generated in the absorption region 20 of the same photodiode. Consequently, the MTF of an array 1 produced according to this first embodiment is improved.

According to the second of these two embodiments, as illustrated in FIG. 3B, the coverage region 10 has a doping type opposite that of the absorption region 20, preferably P-type, thus forming a p-n junction with the absorption region 20 in each diode of the array 1. The p-n junction thus makes it possible to individually collect the holes generated in the absorption region 20. The absorption regions of each photodiode 100a, 100b being non-contiguous, the charge carriers separated by each p-n junction of an individual photodiode are therefore those generated in the absorption region 20 of the same photodiode. Due to this, the MTF of an array 1 produced according to this second embodiment is improved. Furthermore, the collection region 30 has the same doping type as that of the absorption region 20, preferably N-type. This favours a good ohmic contact with the pad 50.

### Example of a Manufacturing Method Making it Possible to Obtain an Array According to the Invention

The array 1 according to the invention, comprising all the elements detailed above, can be produced according to a method comprising the following successive steps:
1. An epitaxially grown layer, preferably based on a CdHgTe material, is first manufactured on a substrate, preferably based on a CdZnTe material, by liquid phase growth or by molecular jet.
2. A doping species is implanted locally at a plurality of zones of the epitaxially grown layer. These zones will form the collection regions 30 of each photodiode 100a, 100b of the array 1, even several arrays 1. The doping species is preferably an acceptor-type dopant, preferably taken from among the element As and the element Sb.
3. A passivation layer 40 is then deposited on the epitaxially grown layer.
4. The assembly is then annealed, preferably under Hg pressure, in order to activate the localised dopant, thus forming the collection regions 30. The annealing further makes it possible to fill the potential gaps with Hg ions and to obtain an N-type doping in the epitaxially grown layer, in order to form the absorption regions 20. This annealing will also make it possible to form the gap opening zones 60 by interdiffusion with the passivation layer 40 which, preferably, is produced based on the same semiconductive material as that of the absorption regions 20.
5. The openings 45a, 45b in the passivation layer 40 are then locally etched, each opening 45a, 45b facing a distinct collection region 30.
6. The pads 50 based on an electrically conductive material are then deposited locally at each photodiode 100a, 100b of each array 1, in the openings 45a, 45b of the passivation layer 40 and preferably also in contact with the lower face 40b of the passivation layer 40.
7. An etching in the substrate is performed at the periphery of each detection array 1, in order to form an opening associated with each detection array 1. A continuous metal layer is then formed locally on the pads 50 of each photodiode array, as well as in the opening associated with the array considered, thus forming through a collective contact at all the photodiodes 100a, 100b of each array 1.
8. The arrays 1 produced by the same wafer are then cut, to obtain an assembly of preferably identical arrays 1. The following steps are therefore carried out independently on each array, making reference to the array 1 of the present invention.
9. The array 1 is then hybridised on a readout circuit, performed in Si-CMOS technology.
10. The substrate on which the epitaxially grown layer has been formed is then removed by polishing, or by chemical etching, or a combination of both.
11. The absorption regions 20 of the array 1 are then structured in a convex shape. The structuring is preferably performed by the transfer of a greyscale lithography, which forms a complex structure in a resin layer. The convex structure is then transferred into the absorption region 20 by a dry etching, preferably an ion etching.
12. The electric properties of a superficial part of the absorption region 20 are then modified by a high doping level to form the coverage region 10. This doping is preferably N-type, which induces an effective gap opening by Moss-Burstein effect. The modification of the doping and of the bandgap of the coverage region 10 can be obtained by ion implantation of an element acting as a donor in the semiconductor, such as the element B.

This method can be implemented to manufacture one single array or several distinct arrays on the substrate. These steps can indeed be carried out simultaneously to form several photodiodes, but also several arrays.

The invention is not limited to the embodiments described above, and extends to all the embodiments covered by the invention.

1. An array of at least two photodiodes, wherein each photodiode comprises an absorption region and a capture region, the capture region comprising an electrically conductive pad, the absorption region being in contact with the capture region, the absorption region being configured to absorb an incident radiation on the photodiode and to enable a diffusion of charge carriers, and wherein each absorption region is separated from the other absorption regions, wherein the absorption region of each photodiode has a convex shape towards the incident radiation.

2. The array according to claim 1, wherein each photodiode further comprises a coverage region based on a first semiconductor, the coverage region covering an upper face of the absorption region facing the incident radiation, the coverage region having a first bandgap energy E₁₀.

3. The array according to claim 2, wherein the first bandgap energy E₁₀ is greater than 0.41 eV.

4. The array according to claim 2, wherein the absorption region has a second bandgap energy E₂₀, with E₁₀>E₂₀.

5. The array according to claim 2, wherein the upper face of the coverage region facing the incident radiation, has a convex surface towards the incident radiation.

6. The array according to claim 1, wherein the absorption region of each photodiode has a curvilinear convex shape.

7. The array according to claim 6, wherein the absorption region of each photodiode has a circular arc shape.

8. The array according to claim 1, wherein the capture region further comprises a collection region located between the absorption region and the electrically conductive pad, the collection region being based on a third semiconductor, the collection region being in contact with the absorption region and with the electrically conductive pad.

9. The array according to claim 1, comprising a passivation layer in contact with a lower face of the absorption region opposite an upper face of the absorption region facing the incident radiation, the passivation layer having openings, each opening facing the absorption region of a distinct photodiode, the capture region of said photodiode extending into said opening.

10. The array according to claim 1, wherein the absorption region contains a gap opening zone extending from a lower face of the absorption region opposite an upper face of the absorption region facing the incident radiation, the gap opening zone having a variation of its bandgap energy along a direction, called normal direction, substantially perpendicular to the lower face of the absorption region.

11. The array according to claim 2, wherein the coverage region and the absorption region are doped, the coverage region having the same doping type as that of the absorption region.

12. The array according to claim 8, wherein the collection region has a doping type opposite that of the absorption region.

13. The array according to claim 2, wherein the coverage region and the absorption region are doped, the coverage region having a doping type opposite that of the absorption region.

14. The array according to claim 8, wherein the collection region and the absorption region have the same doping type.

15. The array according to claim 2, wherein the coverage regions of at least two of the photodiodes form a continuous layer.

16. The array according to claim 1, wherein the absorption region has a doping level less than 10¹⁶ cm⁻³.

17. The array according to claim 2, wherein the coverage region has a doping level greater than 10¹⁶ cm⁻³.

18. The array according to claim 8, wherein the collection region has a doping level greater than 10¹⁶ cm⁻³.
